(19) United States
(12) Patent Application Publication
(10) Pub. No.: US 2025/0149106 A1
(43) Pub. Date: May 8, 2025

(54) MEMORY DEVICE FOR REPAIRING INPUT DATA DURING PROGRAM SUSPEND OPERATION, MEMORY SYSTEM INCLUDING THE SAME AND OPERATION METHOD OF THE SAME

(71) Applicants: SK hynix Inc., Gyeonggi-do (KR); SK hynix NAND Product Solutions Corp. (dba Solidigm), Rancho Cordova, CA (US)

(72) Inventors: Hee Joung PARK, Gyeonggi-do (KR); Chang Han SON, Gyeonggi-do (KR); Hyun Seob SHIN, Gyeonggi-do (KR); Myung Su KIM, Gyeonggi-do (KR); Sung Hun KIM, Gyeonggi-do (KR); Kang Woo PARK, Gyeonggi-do (KR); Ming ZHANG, Rancho Cordova, CA (US); Yogesh WAKCHAURE, Rancho Cordova, CA (US); Curtis GITTENS, Rancho Cordova, CA (US); Zion KWOK, Rancho Cordova, CA (US); Bing XIAO, Rancho Cordova, CA (US); Hui-chun WU, Rancho Cordova, CA (US)

(21) Appl. No.: 18/824,841

(22) Filed: Sep. 4, 2024

Related U.S. Application Data
(60) Provisional application No. 63/596,875, filed on Nov. 7, 2023.

(51) Int. Cl. G11C 29/44

(52) U.S. Cl. CPC G11C 29/44

(57) ABSTRACT

A memory system comprising a memory device including a plurality of memory cells coupled between a plurality of word lines and a plurality of bit lines and a plurality of latches coupled to the bit lines, and configured to program input data stored in the latches into memory cells of a selected word line during a program operation, and output, as information data, at least one or more data among first data stored in the latches and second data stored in the memory cells of the selected word line during a program suspend operation for suspending the program operation, and a controller configured to repair the input data by performing a set logic operation on the information data from the memory device, and apply the set logic operation whose type is different according to an execution moment of the program suspend operation.

### CROSS-REFERENCE TO RELATED APPLICATIONS

This application claims priority under 35 U.S.C. § 119 to U.S. Provisional Patent Application No. 63/596,875, filed on Nov. 7, 2023, which is incorporated herein by reference in its entirety.

### BACKGROUND

### 1. Field

Embodiments of the present disclosure relate to a semiconductor device, and more particularly, to a memory device for repairing input data during a program suspend operation, a method for operating the memory device, and a memory system including the memory device.

### 2. Description of the Related Art

Among diverse semiconductor devices that are generally realized using semiconductors such as silicon (Si), germanium (Ge), gallium arsenide (GaAs), indium phosphide (InP) and the like, devices using a memory system as a storage medium, for example, mobile digital electronic devices such as digital cameras, smartphones, tablet PCs and the like, may include volatile memory devices and nonvolatile memory devices to store data. Volatile memory devices are memory devices in which the stored data are lost when the power supply is cut off. Non-limiting examples of the volatile memory devices may include a Static Random Access Memory (SRAM), a Dynamic Random Access Memory (DRAM), a Synchronous DRAM (SDRAM) and the like. Nonvolatile memory devices are memory devices in which the stored data are retained even when the power supply is cut off. Non-limiting examples of the nonvolatile memory devices may include a Read Only Memory (ROM), a Programmable ROM (PROM), an Electrically Programmable ROM (EPROM), an Electrically Erasable and Programmable ROM (EEPROM), a flash memory device, a Phase-change RAM (PRAM), a Magnetic RAM (MRAM), a Resistive RAM (RRAM), a Ferroelectric RAM (FRAM) and the like.

In a flash memory device, it may be required to perform a read operation while a program operation is being performed. When a read operation is requested to be performed during a program operation, the read operation may need to wait without being performed until the program operation is completed, which may deteriorate the quality of service (QOS) of the flash memory device.

Therefore, in a flash memory device, when a read operation is requested to be performed while a program operation is being performed, the program operation which is being performed may be suspended, and then the requested read operation may be performed. After the requested read operation is completed, the suspended program operation may be resumed.

The program operation of the flash memory device generally uses an Incremental Step Pulse Program (ISPP) method to move the threshold voltage level of the memory cells coupled to a program target word line to a target level corresponding to the input data stored in a page buffer.

The ISPP-based program operation means a program operation that repeatedly operates a program loop including a bit line setup operation, a program pulse application operation, and a verification operation performed at least twice or more, and the value of the input data stored in the page buffer may change every time the verification operation is performed.

Therefore, when a program suspend operation is performed while a program operation is being performed, the data stored in the page buffer may have a value that is different from the value of the data stored in the page buffer before the program operation begins.

### SUMMARY

Embodiments of the present disclosure are directed to a memory device that may efficiently repair input data when a program suspend operation is performed while a program operation is being performed, a method for operating the memory device, and a memory system including the memory device.

The technical problems desired to be achieved in the embodiments of the present disclosure are not limited to the technical problems mentioned above, and other technical problems not mentioned above may also be clearly understood by those of ordinary skill in the art to which the present disclosure pertains from the description below.

In accordance with an embodiment of the present disclosure, a memory system a memory system may include: a memory device including a plurality of memory cells coupled between a plurality of word lines and a plurality of bit lines and a plurality of latches coupled to the bit lines, and configured to: program input data stored in the latches into memory cells of a selected word line during a program operation, and output, as information data, at least one or more data among first data stored in the latches and second data stored in the memory cells of the selected word line during a program suspend operation for suspending the program operation; and a controller configured to: repair the input data by performing a set logic operation on the information data from the memory device, and apply the set logic operation whose type is different according to an execution moment of the program suspend operation.

In accordance with another embodiment of the present disclosure, a memory device may include: a memory cell array including a plurality of memory cells coupled between a plurality of word lines and a plurality of bit lines; a page buffer including a plurality of first latches corresponding to the bit lines, respectively; and a control logic configured to: program input data stored in the first latches into memory cells of a selected word line during a program operation, repair the input data by performing a set logic operation on at least one or more data among first data and second data during a program suspend operation for suspending the program operation, the first data stored in the first latches, the second data stored in the memory cells of the selected word line, and apply the set logic operation whose type is different according to an execution moment of the program suspend operation.

In accordance with another embodiment of the present disclosure, a method for operating a memory device, the method may include: performing a program operation of programming input data stored in a page buffer into a memory cell selected as a program target; repairing the input data by performing a set logic operation on at least one data among first data stored in the page buffer and second data stored in the selected memory cell during a program suspend operation after the program operation; and detecting an execution moment of the program suspend operation to produce a detection result and selecting a type of the set logic operation to be applied to the repairing of the input data based on the detection result.

### BRIEF DESCRIPTION OF THE DRAWINGS

FIG. 1 illustrates a memory system in which a repair operation is performed during a program suspend operation in accordance with an embodiment of the present disclosure.

FIGS. 2A to 2C illustrate a repair operation performed between the constituent elements included in a controller of the memory system shown in FIG. 1.

FIGS. 3A to 3C illustrate a repair operation performed between the controller and the memory device of the memory system shown in FIG. 1.

FIG. 4 illustrates a memory device in which a repair operation is performed during a program suspend operation in accordance with an embodiment of the present disclosure.

FIGS. 5A to 5C illustrate a repair operation performed between the constituent elements of the memory device shown in FIG. 4.

FIG. 6 illustrates an operation sequence of a repair operation during a program suspend operation and a set logic operation applied to the repair operation in accordance with an embodiment of the present disclosure.

FIG. 7 illustrates a program operation using an Incremental Step Pulse Program (ISPP) method.

FIG. 8 illustrates a moment when a program suspend operation is performed during an ISPP-based program operation.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language includes hardware—for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits.

According to an embodiment, the data item may include a discrete object. According to another embodiment, the data item may include a unit of information within a transmission packet between two different components.

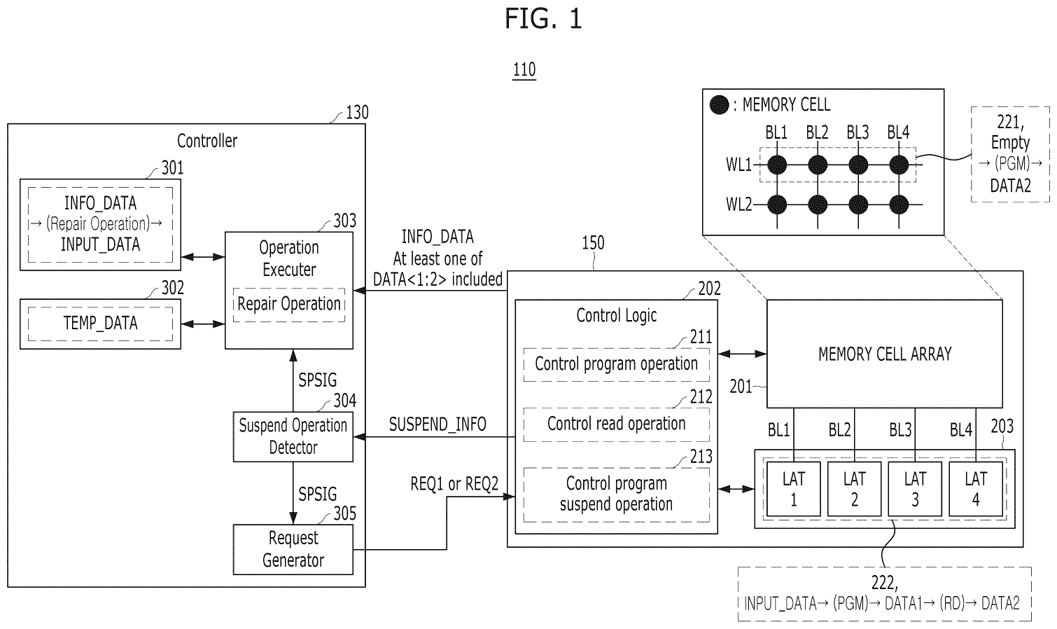

FIG. 1 illustrates a memory system 110 in which a repair operation is performed during a program suspend operation in accordance with an embodiment of the present disclosure.

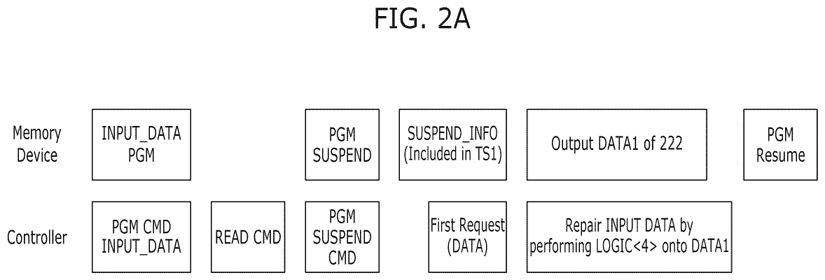

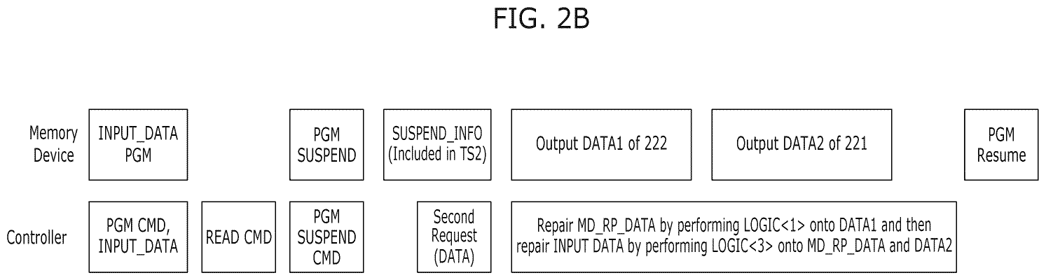

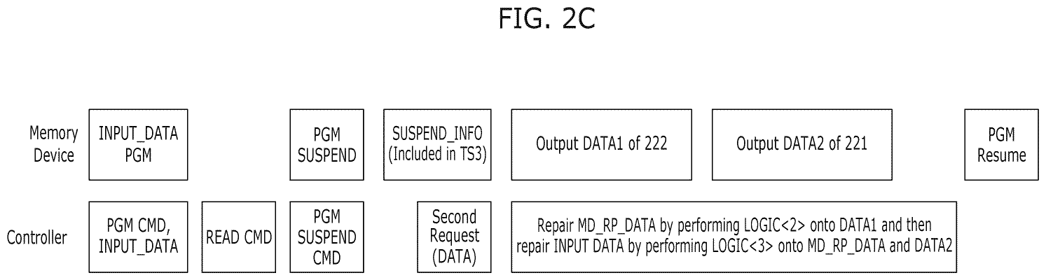

FIGS. 2A to 2C illustrate a repair operation performed between a controller and a memory device of the memory system 110 shown in FIG. 1.

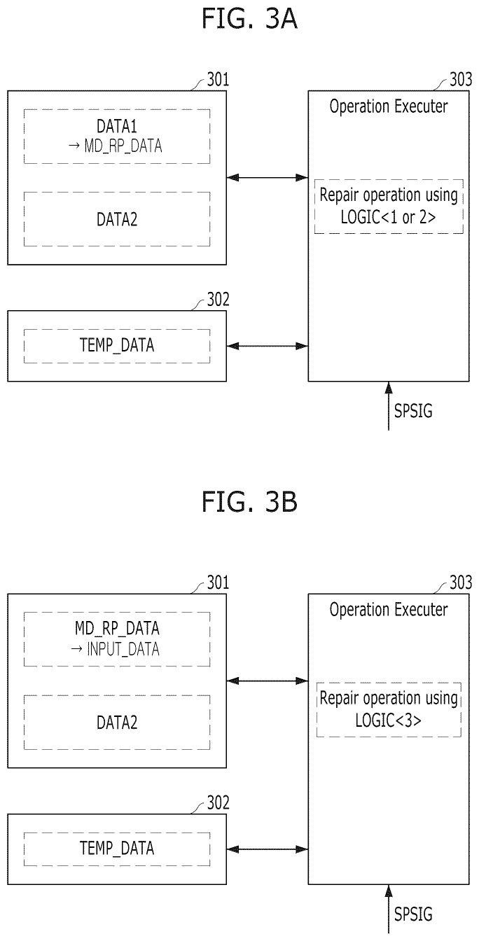

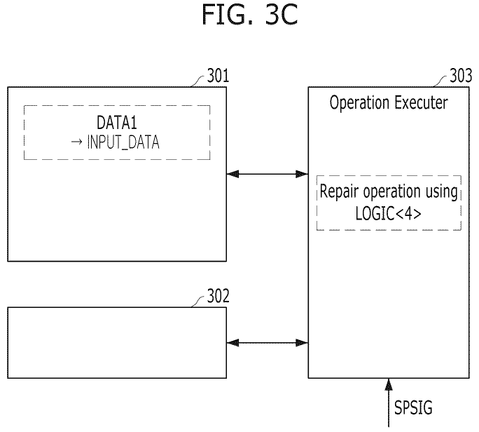

FIGS. 3A to 3C illustrate a repair operation performed between the constituent elements included in the controller of the memory system 110 shown in FIG. 1.

Referring to FIG. 1, the memory system 110 in accordance with the embodiment of the present disclosure may include a controller 130 and a memory device 150. The memory device 150 may include a memory cell array 201, a control logic 202, and a page buffer 203. The page buffer 203 may include a plurality of latches 222. The controller 130 may include a first buffer 301, a second buffer 302, an operation executer 303, a suspend operation detector 304, and a request generator 305.

The controller 130 may control the overall operation of the memory system 110. The controller 130 may control the memory device 150 to perform operations such as a read operation, a program operation, an erase operation, a program suspend operation, and a program resume operation corresponding to the commands input from an external device such as a host. Alternatively, the controller 130 may control the memory device 150 to perform an operation independently regardless of the command input from the external device.

The memory device 150 may receive a command and an address from the controller 130 and access to an area of the memory cell array 201 which is selected based on the address. The memory device 150 may perform an operation directed by the command for the area selected based on the address. For example, the memory device 150 may perform a write operation (program operation), a read operation, an erase operation, a program suspend operation and a program resume operation. During a program operation, the memory device 150 may program data in the area selected based on the address. During a read operation, the memory device 150 may read the data from the area selected based on the address. During an erase operation, the memory device 150 may erase the data stored in the area selected based on the address. During a program suspend operation and a program resume operation, the memory device 150 may suspend an operation of programming data in an area selected based on a program address, perform an operation of reading data in an area selected based on a read address, and then perform the operation of programming the data in the area selected based on the program address again.

In FIG. 1, the memory cell array 201 included in the memory device 150 may include a plurality of memory cells MEMORY CELL that are coupled between a plurality of word lines WL<1:2> and a plurality of bit lines BL<1:4>. Although the embodiment is illustrated in the figure where the memory cell array 201 includes two word lines and four bit lines, more word lines and more bit lines may be included in the memory cell array 201.

The memory cells MEMORY CELL may include single-level cells SLC each of which stores one bit of data, multi-level cells MLC each of which stores two bits of data, triple-level cells TLC each of which stores three bits of data, or quad-level cells QLC each of which may store four bits of data. In the following description, each of the memory cells MEMORY CELL is a triple-level cell TLC.

The page buffer 203 included in the memory device 150 may include a plurality of latches 222, e.g., 4 latches. The latches 222 may be coupled to the memory cell array 201 through the bit lines BL<1:4>, respectively. The latches 222 may operate in response to the control of the control logic 202.

In particular, during a program operation, the memory device 150 may program input data INPUT_DATA stored in the latches 222 into a plurality of memory cells (which will be, hereinafter, referred to as ‘program cells’) coupled to a word line (which will be, hereinafter, referred to as ‘a program word line’) selected as a program target. During a program suspend operation, the memory device 150 may output, to the controller 130, at least one or more data among first data DATA1 stored in the latches 222 and second data DATA2 stored in the program cells as information data INFO_DATA.

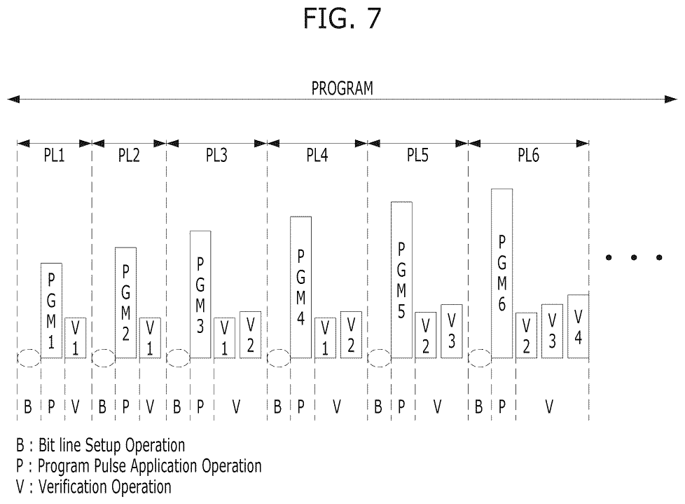

To be more specific, referring to FIG. 7 together with FIG. 1, the program operation PROGRAM generally uses the Incremental Step Pulse Program (ISPP) method to move the threshold voltage level of the program cells to a target level corresponding to the input data stored in the page buffer. Here, the ISPP-based program operation may mean a program operation that repeatedly operates multiple program loops, e.g., PL1, PL2, PL3, PL4, PL5, PL6. Each program loop includes a bit line setup operation B, a program pulse application operation P and a verification operation V performed at least twice or more.

In the bit line setup operation B included in each of the program loops PL1, PL2, PL3, PL4, PL5, PL6, the memory device 150 may set up the voltage level of each of the bit lines BL<1:4> according to the value of the input data INPUT_DATA stored in the latches 222. For example, the memory device 150 may set up each of the bit lines BL<1:4> to a program allowable voltage (e.g., a ground voltage) or a program prohibition voltage (e.g., a power supply voltage).

In the program pulse application operation P included in each of the program loops PL1, PL2, PL3, PL4, PL5, PL6, the memory device 150 may adjust the threshold voltage level of the program cells by applying, to the program word line, program pulses PGM1, PGM2, PGM3, PGM4, PGM5, PGM6. For example, the memory device 150 may increase the threshold voltage level of the program cells coupled to a bit line with the program allowable voltage set up therein among the bit lines BL<1:4> and maintain the threshold voltage level of the program cells coupled to the bit line with the program prohibition voltage set up therein.

In the verification operation V included in each of the program loops PL1, PL2, PL3, PL4, PL5, PL6, the memory device 150 may verify whether the threshold voltage level of the program cells is greater than or equal to the level of the verification voltage V1, V2, V3, V4 by applying the verification voltage V1, V2, V3, V4 to the program word line. For example, in the case of a program cell in which verification is changed from a failure state to a pass state through a program pulse application operation P included in each of the program loops PL1, PL2, PL3, PL4, PL5, PL6, that is, in the case of a program cell whose threshold voltage level is changed from a level less than a verification voltage level to a level greater than or equal to the verification voltage level through a program pulse application operation, the memory device 150 may change the value of the data stored in the latches 222 in order to set up the program prohibition voltage in the coupled bit line during the bit line setup operations B of the subsequent program loop PL2, PL3, PL4, PL5, PL6. Therefore, the input data INPUT_DATA stored in the latches 222 before the beginning of a program operation may be changed to the first data DATA1 during the progress of the program operation PGM. Similarly, a program cell that is empty (i.e., no data are stored therein) before the beginning of the program operation may have the second data DATA2 during the progress of the program operation PGM. Here, each of the first data DATA1 and the second data DATA2 may have a value that is different from that of the input data INPUT_DATA.

As the program loops PL1, PL2, PL3, PL4, PL5, PL6 included in the program operation PROGRAM are sequentially performed, the number of the program cells that are changed from a failure state to a pass state through the verification operation V included in each of the program loops PL1, PL2, PL3, PL4, PL5, PL6 may be increased. Therefore, when the number of the program cells that passed the verification operation V exceeds a reference number or the number of the program cells that failed the verification operation V is less than or equal to a specific number, the memory device 150 may determine the program operation PROGRAM as a success and terminate the program operation PROGRAM. Even after repeating a predetermined number of program loops, when the number of the program cells that passed the verification operation V is less than or equal to the reference number or the number of the program cells that failed the verification operation V exceeds the specific number, the memory device 150 may determine the program operation PROGRAM as a failure and terminate the program operation PROGRAM.

In some embodiments, the controller 130 may perform a set logic operation included in a repair operation on the information data INFO_DATA input from the memory device 150 to repair the input data INPUT_DATA.

In particular, the controller 130 may detect a moment when the program suspend operation begins and may apply a different type of the set logic operation included in the repair operation according to the detection result.

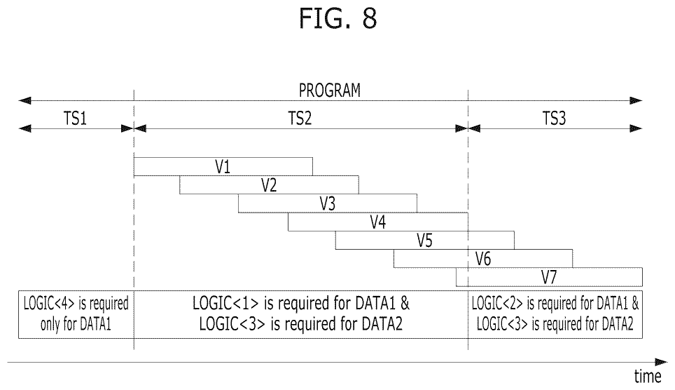

To be more specific, referring to FIG. 8 together with FIG. 1, the controller 130 may categorize the execution moment of the program suspend operation into three cases below. Further, the controller 130 may apply a different type of the set logic operation included in the repair operation according to the case of the execution moment of the program suspend operation.

A first case is that the program suspend operation begins in a state TS1 in which there are no cells whose threshold voltage level has reached a target level among program cells. For example, in the case of a triple-level cell TLC, there may be seven target levels V1, V2, V3, V4, V5, V6 and V7 for program cells. Here, a case that the execution moment of the program suspend operation is positioned before the moment when the threshold voltage level of all program cells is confirmed to be less than a first target level V1 may be considered as the case that there are no cells whose threshold voltage level has reached the target level among the program cells.

A second case is that the program suspend operation begins in a state TS2 in which the number of cells whose threshold voltage level has reached the target level among program cells is one or more and less than or equal to a predetermined number. For example, a case that the execution moment of the program suspend operation is positioned between a moment when at least one cell targeting the first target level V1 among the program cells, which are triple-level cells TLCs, is confirmed to have a threshold voltage level which is greater than or equal to the first target level V1 and a moment when all cells (or cells greater than or equal to a specific number) targeting a fourth target level V4 among the program cells are confirmed to have a threshold voltage level which is greater than or equal to the fourth target level V4 may be considered as the case that the number of the cells whose threshold voltage level has reached the target level among the program cells is one or more and less than or equal to the predetermined number.

The third case is that the program suspend operation begins in a state TS3 in which the number of cells whose threshold voltage level has reached the target level among the program cells exceeds a predetermined number. For example, a case that the execution moment of the program suspend operation is positioned between a moment when all cells (or cells greater than or equal to a specific number) targeting the fourth target level V4 among the program cells which are triple-level cells TLC are confirmed to have a threshold voltage level which is greater than or equal to the fourth target level V4 and a moment when all cells (or cells greater than or equal to a specific number) targeting a seventh target level V7 among the program cells are confirmed to have a threshold voltage level which is greater than or equal to the seventh target level V7 may be considered as the case where the number of the cells whose threshold voltage level has reached the target level among the program cells exceeds the predetermined number. Here, the program operation PROGRAM may be terminated at the moment when all cells (or cells greater than or equal to the specific number) targeting the seventh target level V7 among the program cells, which are triple-level cells TLC, are confirmed to have a threshold voltage level which is greater than or equal to the seventh target level V7.

Referring to FIGS. 2A and 2B together with FIG. 1, the controller 130 may apply a program command PGM CMD and input data INPUT_DATA to the memory device 150. The memory device 150 may program (PGM) the input data INPUT_DATA into the program cells in response to the program command PGM CMD.

The controller 130 may transfer a read command READ CMD to the memory device 150 before the program operation is completed, and then transfer a program suspend command PGM SUSPEND CMD to the memory device 150. The memory device 150 may suspend the program operation in response to the program suspend command PGM SUSPEND CMD which is input from the controller 130 and output, to the controller 130, program suspend information SUSPEND_INFO indicating the extent of the progress of the program operation. Here, the embodiment of the figures illustrates that the controller 130 transfers a read command READ CMD to the memory device 150 after transferring the program command PGM CMD and then transfers a program suspend command PGM SUSPEND CMD to the memory device 150. However, in other embodiments, the controller 130 may transfer, to the memory device 150, commands other than the read command READ CMD, such as a command for a background operation, and then transfer, to the memory device 150, a program suspend command PGM SUSPEND CMD.

The controller 130 may detect the execution moment of the program suspend operation based on the program suspend information SUSPEND_INFO that is input from the memory device 150. The controller 130 may transmit a request REQ1 or REQ2 to the memory device 150 to transfer at least one or more data among the first data DATA1 and the second data DATA2 as the information data INFO_DATA based on the detection result.

The memory device 150 may output, to the controller 130, at least one or more data among the first data DATA1 and the second data DATA2 as the information data INFO_DATA according to the request REQ1 or REQ2 input from the controller 130.

The controller 130 may determine the type of a logic operation to be applied among the types of the set logic operations included in the repair operation according to the program suspend information SUSPEND_INFO input from the memory device 150. Then, the controller 130 may perform the repair operation on the information data INFO_DATA input from the memory device 150 by using the determined logic operation.

Referring to FIG. 2A, when a result of checking the program suspend information SUSPEND_INFO input from the memory device 150 is that the program suspend operation begins in the state TS1 in which there are no cells whose threshold voltage level has reached the target level among the program cells, the controller 130 may generate a first request REQ1 and transfer the first request REQ1 to the memory device 150.

The memory device 150 may output, to the controller 130, the first data DATA1 stored in the latches 222 as the information data INFO_DATA in response to the first request REQ1 input from the controller 130. In this way, when the first request REQ1 is transferred from the controller 130, the memory device 150 may not read the second data DATA2 stored in the program cells.

The controller 130 may store, in the first buffer 301, the information data INFO_DATA including only the first data DATA1 input from the memory device 150. Then, the controller 130 may repair the input data INPUT_DATA by performing a fourth logic operation LOGIC<4> on the first data DATA1 of the first buffer 301. The controller 130 may convert the first data DATA1 stored in the first buffer 301 into the input data INPUT_DATA through the fourth logic operation LOGIC<4>.

Referring to FIG. 2B, when a result of checking the program suspend information SUSPEND_INFO input from the memory device 150 is that the program suspend operation begins in the state TS2 in which the number of the cells whose threshold voltage level has reached the target level among the program cells is one or more and less than or equal to a predetermined number, the controller 130 may generate a second request REQ2 and transfer the second request REQ2 to the memory device 150.

The memory device 150 may output, to the controller 130, the first data DATA1 stored in the latches 222 in response to the second request REQ2 that is input from the controller 130. Then, the memory device 150 may perform a read operation of reading the second data DATA2 stored in the program cells and outputting the second data DATA2 to the latches 222. In this way, as the read operation is performed, the first data DATA1 stored in the latches 222 may be replaced with the second data DATA2, and the memory device 150 may output, to the controller 130, the second data DATA2 stored in the latches 222 through the read operation. Accordingly, the memory device 150 may output, to the controller 130, both first data DATA1 and second data DATA2 as the information data INFO_DATA.

The controller 130 may store, in the first buffer 301, the information data INFO_DATA including both first data DATA1 and second data DATA2 input from the memory device 150. Then, the controller 130 may perform a first repair operation of generating intermediate repair data MD_RP_DATA by performing a first logic operation LOGIC<1> on the first data DATA1 of the first buffer 301. The controller 130 may convert the first data DATA1 stored in the first buffer 301 into the intermediate repair data MD_RP_DATA through the first logic operation LOGIC<1>. Subsequently, the controller 130 may perform a second repair operation of repairing the input data INPUT_DATA by performing a third logic operation LOGIC<3> on the intermediate repair data MD_RP_DATA and the second data DATA2 of the first buffer 301. The controller 130 may convert the intermediate repair data MD_RP_DATA into the input data INPUT_DATA through the third logic operation LOGIC<3>. Temporary data TEMP_DATA may be generated in the process of performing the above-described first logic operation LOGIC<1> and the third logic operation LOGIC<3>, and the controller 130 may store the temporary data TEMP_DATA in the second buffer 302.

Referring to FIG. 2C, when a result of checking the program suspend information SUSPEND_INFO input from the memory device 150 is that the program suspend operation begins in the state TS3 in which the number of the cells whose threshold voltage level has reached the target level among the program cells exceeds the predetermined number, the controller 130 may generate a second request REQ2 and transfer the generated second request REQ2 to the memory device 150.

In response to the second request REQ2 input from the controller 130, the memory device 150 may output the first data DATA1 stored in the latches 222 to the controller 130. Then, the memory device 150 may perform a read operation of reading the second data DATA2 stored in the program cells and outputting the second data DATA2 to the latches 222. In this way, as the read operation is performed, the first data DATA1 stored in the latches 222 may be replaced with the second data DATA2, and the memory device 150 may output, to the controller 130, the second data DATA2 stored in the latches 222 through the read operation. Accordingly, the memory device 150 may output, to the controller 130, both first data DATA1 and second data DATA2 as the information data INFO_DATA.

The controller 130 may store, in the first buffer 301, information data INFO_DATA including both first data DATA1 and second data DATA2 input from the memory device 150. Then, the controller 130 may perform a first repair operation of generating the intermediate repair data MD_RP_DATA by performing a second logic operation LOGIC<2> on the first data DATA1 of the first buffer 301. The controller 130 may convert the first data DATA1 stored in the first buffer 301 into the intermediate repair data MD_RP_DATA through the second logic operation LOGIC<2>. Subsequently, the controller 130 may perform a second repair operation of repairing the input data INPUT_DATA by performing a third logic operation LOGIC<3> on the intermediate repair data MD_RP_DATA and the second data DATA2 of the first buffer 301. The controller 130 may convert the intermediate repair data MD_RP_DATA into the input data INPUT_DATA through the third logic operation LOGIC<3>.

In the process of performing the above-described second logic operation LOGIC<2> and the third logic operation LOGIC<3>, temporary data TEMP_DATA may be generated, and the controller 130 may store the temporary data TEMP_DATA in the second buffer 302.

During a program resume operation PGM RESUME, the controller 130 may resume the suspended program operation by transferring, to the memory device 150, the input data INPUT_DATA repaired through the above-described repair operation. Although not specified in the drawing, the memory device 150 may perform a read operation corresponding to a read command READ CMD input from the controller 130 at a moment between the moment when the program operation is suspended PGM SUSPEND in response to a program suspend command PGM SUSPEND CMD input from the controller 130 and the moment when the program resume operation PGM RESUME is performed.

Referring back to FIG. 1, according to an embodiment of the present disclosure, the memory system 110 may be realized as one of diverse types of storage devices, for example, a Solid State Drive (SSD), a Multi-Media Card (MMC) such as a multi-media card (MMC), an embedded MMC (eMMC), a reduced size MMC (RS-MMC), and a micro-MMC, a Secure Digital (SD) card such as an SD, a mini-SD, and a micro-SD, a Universal Storage Bus (USB) storage device, a Universal Flash Storage (UFS) device, a Compact Flash (CF) card, a smart media card, a memory stick, and the like.

According to an embodiment of the present disclosure, the memory device 150 may be a volatile memory device, such as a Double Data Rate Synchronous Dynamic Random Access Memory (DDR SDRAM), a Low Power Double Data Rate4 Synchronous Dynamic Random Access Memory (LPDDR4 SDRAM), a Graphics Double Data Rate SDRAM (GDDR SDRAM), a Low Power DDR (LPDDR), and a Rambus Dynamic Random Access Memory (RDRAM). According to another embodiment of the present disclosure, the memory device 150 may be a nonvolatile memory device, such as a NAND flash memory, a Vertical NAND, a NOR flash memory, a resistive Random Access Memory (RRAM), a phase-change Random Access Memory (PRAM), a magneto-resistive Random Access Memory (MRAM), a ferroelectric Random Access Memory (FRAM), a Spin Transfer Torque Random Access Memory (STT-RAM), and the like. In the following description, the embodiments may be described based on the memory device 150 being a NAND flash memory.

The control logic 202 included in the memory device 150 may control 211 a program operation for a selected area of the memory cell array 201, control 212 a read operation, and control 213 a program suspend operation and a program resume operation. The control logic 202 may drive the memory cell array 201 to control the program operation, the read operation, the program suspend operation, and the program resume operation. For example, the control logic 202 may apply diverse operation voltages to the word lines WL<1:4> and the bit lines BL<1:4> included in the memory cell array 201, or discharge the applied voltage.

During a program operation, the control logic 202 may store the input data INPUT_DATA received from the controller 130 in the latches 222 included in the page buffer 203. Subsequently, the control logic 202 may store the input data INPUT_DATA stored in the latches 222 in the program cells through the bit lines BL<1:4>.

During a read operation, the control logic 202 may read the data stored in the memory cells coupled to a word line that is selected as a read target through the bit lines BL<1:4> and store the read data in the latches 222 included in the page buffer 203. Subsequently, the control logic 202 may output, to the controller 130, the data stored in the latches 222 through the read operation.

During a program suspend operation, the control logic 202 may output, to the controller 130, at least one data among the first data DATA1 stored in the latches 222 included in the page buffer 203 and the second data DATA2 stored in the program word line as the information data INFO_DATA. As described in the program operation above with reference to FIGS. 1 and 7, the value of each of the first data DATA1 stored in the latches 222 and the second data DATA2 stored in the program cells during the program suspend operation may be different from the value of the input data INPUT_DATA.

The suspend operation detector 304 included in the controller 130 may detect the execution moment of the program suspend operation based on the program suspend information SUSPEND_INFO that is input from the memory device 150. Then, the suspend operation detector 304 may generate a suspend confirmation signal SPSIG based on the detection result. Also, the suspend operation detector 304 may detect the number of the cells whose threshold voltage level has reached a target level among the program cells in the program operation, and generate the suspend confirmation signal SPSIG based on the detection result.

To be more specific, the suspend operation detector 304 may generate the suspend confirmation signal SPSIG of three different values according to the three cases of the execution moment of the program suspend operation described above with reference to FIG. 8 together with FIG. 1.

For example, the suspend operation detector 304 may generate a suspend confirmation signal SPSIG having a first value corresponding to the first case, that is, the case where the program suspend operation begins in the state TS1 in which there are no cells whose threshold voltage level has reached the target level among program cells.

For another example, the suspend operation detector 304 may generate a suspend confirmation signal SPSIG having a second value corresponding to the second case, that is, the case where the program suspend operation begins in the state TS2 in which the number of the cells whose threshold voltage level has reached the target level among the program cells is one or more and less than or equal to a predetermined number.

For yet another example, the suspend operation detector 304 may generate a suspend confirmation signal SPSIG having a third value corresponding to the third case, that is, the case where the program suspend operation begins in the state TS3 in which the number of the cells whose threshold voltage level has reached the target level among the program cells exceeds the predetermined number.

The request generator 305 included in the controller 130 may transfer, to the memory device 150, one request among the first request REQ1 and the second request REQ2 in response to the suspend confirmation signal SPSIG. Here, the first request REQ1 may include a command requesting the memory device 150 to output only the first data DATA1 as the information data INFO_DATA. The second request REQ2 may include a command requesting the memory device 150 to output both first data DATA1 and second data DATA2 as the information data INFO_DATA. Here, the request generator 305 may transfer the first request REQ1 to the memory device 150 in response to the suspend confirmation signal SPSIG having the first value, and transfer the second request REQ2 to the memory device 150 in response to the suspend confirmation signal SPSIG having the second and third values.

When the first request REQ1 is transferred from the request generator 305, the memory device 150 may output the first data DATA1 stored in the latches 222 to the controller 130. In this way, when the first request REQ1 is transferred from the request generator 305, the memory device 150 may not read the second data DATA2 stored in the program cells.

When the second request REQ2 is transferred from the request generator 305, the memory device 150 may output, to the controller 130, the first data DATA1 stored in the latches 222. Then, the memory device 150 may perform a read operation of reading the second data DATA2 stored in the program cells into the latches 222. As the read operation is performed, the first data DATA1 stored in the latches 222 may be replaced with the second data DATA2, and the memory device 150 may output, to the controller 130, the second data DATA2 stored in the latches 222 through the read operation.

The operation executer 303 included in the controller 130 may store, in the first buffer 301, the information data INFO_DATA input from the memory device 150. Then, the operation executer 303 may perform a set logic operation corresponding to the suspend confirmation signal SPSIG on the information data INFO_DATA of the first buffer 301 in order to repair the information data INFO_DATA of the first buffer 301 to generate the input data INPUT_DATA. The operation executer 303 may store, in the second buffer 302, temporary data TEMP_DATA generated in the process of performing the set logic operation corresponding to the suspend confirmation signal SPSIG.

To be more specific, referring to FIGS. 3A and 3B together with FIG. 1, the operation executer 303 may allocate two spaces for storing the first data DATA1 and the second data DATA2 in the first buffer 301 in response to the suspend confirmation signal SPSIG having the second value or the third value. The two spaces for storing the first data DATA1 and the second data DATA2 input from the memory device 150 according to the second request REQ2 of the request generator 305 may be allocated to the first buffer 301.

Referring to FIG. 3A together with FIG. 1, the operation executer 303 may store, in the first buffer 301, the first data DATA1 and the second data DATA2 input from the memory device 150. Then, the operation executer 303 may perform a first repair operation of generating the intermediate repair data MD_RP_DATA by performing one logic operation on the first data DATA1 stored in the first buffer 301. The one logic operation may include a logic operation corresponding to the suspend confirmation signal SPSIG, among the first logic operation LOGIC<1> and the second logic operation LOGIC<2>. Here, the operation executer 303 may perform the first logic operation LOGIC<1> on the first data DATA1 stored in the first buffer 301 in response to the suspend confirmation signal SPSIG having the second value to generate the intermediate repair data MD_RP_DATA. The operation executer 303 may perform a second logic operation LOGIC<2> on the first data DATA1 stored in the first buffer 301 in response to the suspend confirmation signal SPSIG having the third value to generate the intermediate repair data MD_RP_DATA. The operation executer 303 may convert the first data DATA1 stored in the first buffer 301 into the intermediate repair data MD_RP_DATA through one logic operation among the first logic operation LOGIC<1> and the second logic operation LOGIC<2>. Here, each of the first logic operation LOGIC<1> and the second logic operation LOGIC<2> may generate the temporary data TEMP_DATA during the logic operation. Therefore, the temporary data TEMP_DATA may be stored in the second buffer 302.

Referring to FIG. 3B together with FIG. 1, after the first repair operation is completed, that is, after the intermediate repair data MD_RP_DATA are stored in the first buffer 301, the operation executer 303 may perform a third logic operation LOGIC<3> on the intermediate repair data MD_RP_DATA and the second data DATA2 of the first buffer 301 to repair the input data INPUT_DATA. The operation executer 303 may convert the intermediate repair data MD_RP_DATA stored in the first buffer 301 into the input data INPUT_DATA through the third logic operation LOGIC<3>. Here, the third logic operation LOGIC<3> may generate the temporary data TEMP_DATA during the logic operation. Therefore, the temporary data TEMP_DATA may be stored in the second buffer 302.

Referring to FIG. 3C together with FIG. 1, the operation executer 303 may allocate one space for storing the first data DATA1 in the first buffer 301 in response to the suspend confirmation signal SPSIG having the first value. One space for storing the first data DATA1 input from the memory device 150 according to the first request REQ1 of the request generator 305 may be allocated to the first buffer 301.

The operation executer 303 may store, in the first buffer 301, the first data DATA1 input from the memory device 150. Then the operation executer 303 may perform the fourth logic operation LOGIC<4> on the first data DATA1 of the first buffer 301 to repair the input data INPUT_DATA. The operation executer 303 may repair the first data DATA1 of the first buffer 301 to generate the input data INPUT_DATA through the fourth logic operation LOGIC<4>. Here, in the case of the fourth logic operation LOGIC<4>, the temporary data TEMP_DATA may not be generated during the logic operation. Therefore, no data may be stored in the second buffer 302.

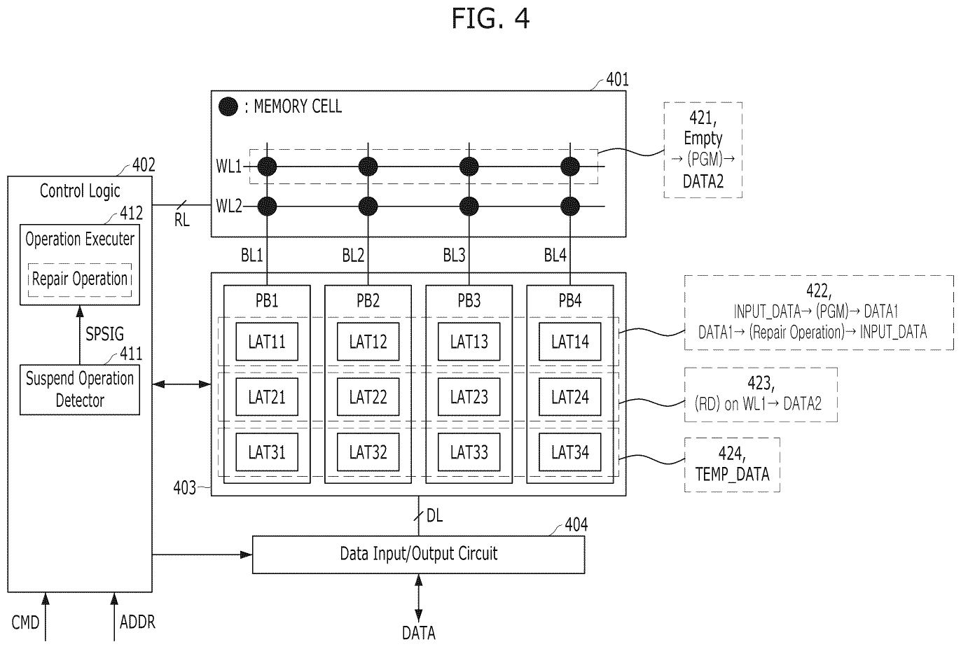

FIG. 4 illustrates a memory device in which a repair operation is performed during a program suspend operation in accordance with an embodiment of the present disclosure.

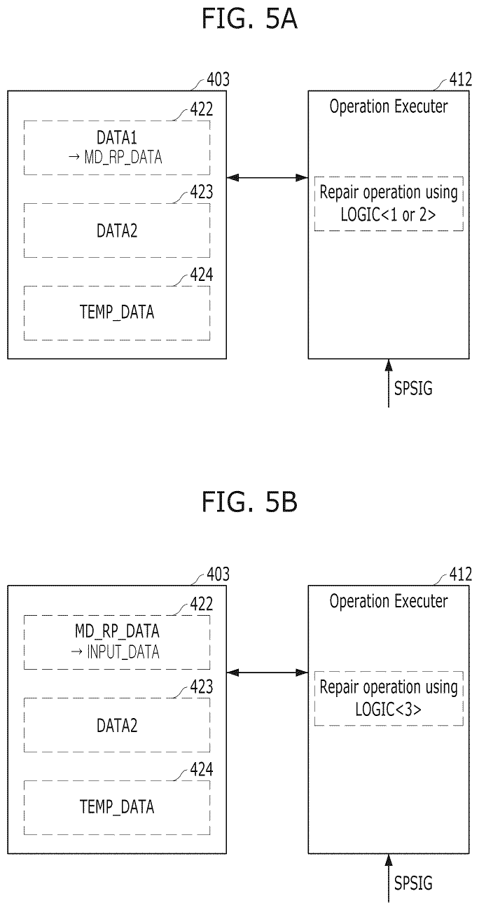

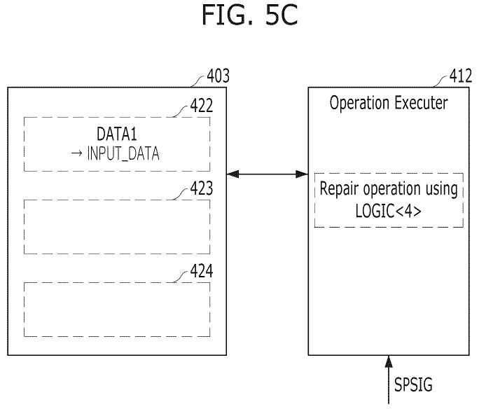

FIGS. 5A to 5C illustrate a repair operation performed between the constituent elements of the memory device shown in FIG. 4.

Referring to FIG. 4, the memory device in accordance with the embodiment of the present disclosure may include a memory cell array 401, a control logic 402, a page buffer 403, and a data input and output (input/output) circuit 404. The page buffer 403 may include a plurality of first latches 422, a plurality of second latches 423, and a plurality of third latches 424. The control logic 402 may include an operation executer 412 and a suspend operation detector 411.

To be specific, the memory cell array 401 may include a plurality of memory cells MEMORY CELL that are coupled between a plurality of word lines WL<1:2> and a plurality of bit lines BL<1:4>. Although it is illustrated that the memory cell array 401 includes two word lines and four bit lines, the memory cell array 401 may include more word lines and more bit lines.

Each of the memory cells MEMORY CELL may be a single-level cell SLC that stores one bit of data, a multi-level cell MLC that stores two bits of data, a triple-level cell TLC that stores three bits of data, or a quad-level cell QLC that may store four bits of data. In the following description, the embodiment of the present disclosure may be described based on each of the memory cells MEMORY CELL being a triple-level cell TLC.

The page buffer 403 may include a plurality of first latches 422, a plurality of second latches 423, and a plurality of third latches 424. Each of the first latches 422, the second latches 423, and the third latches 424 may be coupled to the memory cell array 401 through the bit lines BL<1:4>. Each of the first latches 422, the second latches 423, and the third latches 424 may operate in response to the control of the control logic 402.

The control logic 402 may control a program operation, control a read operation, control a program suspend operation, and a program resume operation for the selected area of the memory cell array 401. Also, the control logic 402 may drive the memory cell array 401 to control the program operation, the read operation, the program suspend operation, and the program resume operation. For example, the control logic 402 may apply diverse operation voltages to the word lines WL<1:4> and the bit lines BL<1:4> included in the memory cell array 401, or discharge the applied voltage.

During a program operation, the control logic 402 may program the input data INPUT_DATA stored in the first latches 422 into a plurality of memory cells (which will be, hereinafter, referred to as ‘program cells’) coupled to a word line selected as a program target (which will be, hereinafter, referred to as ‘a program word line’).

During a read operation, the control logic 402 may read the data stored in a plurality of memory cells that are coupled to a word line which is selected as a read target through the bit lines BL<1:4> and store the data in the first latches 422 included in the page buffer 403. Subsequently, the control logic 402 may output, to the outside, the data stored in the first latches 422 through the read operation.

During the program suspend operation, the control logic 402 may perform a set logic operation on at least one data among the first data DATA1 stored in the first latches 422 and the second data DATA2 stored in the program cells to repair the input data INPUT_DATA.

As described in the program operation described above with reference to FIGS. 1 and 7 together, the value of each of the first data DATA1 stored in the latches used in the program operation, (that is, the latches 222 in FIG. 1 and the first latches 422 in FIG. 4), and the second data DATA2 stored in the program cells may be different from the value of the input data INPUT_DATA during the program suspend operation.

The input data INPUT_DATA stored in the first latches 422 before the program operation begins may be changed into the first data DATA1 during the program operation PGM. Similarly, the empty program cell (i.e., no data are stored therein before the program operation begins) may store the second data DATA2 during the program operation PGM.

During the program suspend operation, the control logic 402 may perform a repair operation on the first data DATA1 stored in the first latches 422 to repair the input data INPUT_DATA. The first data DATA1 stored in the first latches 422 before the repair operation may be converted into the input data INPUT_DATA through the repair operation.

In particular, the control logic 402 in accordance with the embodiment of the present disclosure may detect the moment when the program suspend operation begins to produce a detection result and may apply the set logic operation of the repair operation whose type is different according to the detection result.

To be more specific, the suspend operation detector 411 included in the control logic 402 may detect the execution moment of the program suspend operation and generate a suspend confirmation signal SPSIG based on the detection result. Also, the suspend operation detector 411 may detect the number of the cells whose threshold voltage level has reached the target level among the program cells in the program operation and generate a suspend confirmation signal SPSIG based on the detection result.

To be more specific, just as the suspend confirmation signal SPSIG having the three different values are generated in the suspend operation detector 304 included in the controller 130 according to the three cases that the execution moment of the above-described program suspend operation is categorized, which is described earlier with reference to FIG. 8 together with FIG. 1, the suspend operation detector 411 included in the control logic 402 may also generate the suspend confirmation signal SPSIG having three different values.

For example, the suspend operation detector 411 may generate a suspend confirmation signal SPSIG having a first value corresponding to a first case, that is, a case that the program suspend operation begins in a state TS1 in which there are no cells whose threshold voltage level has reached the target level among the program cells.

For another example, the suspend operation detector 411 may generate a suspend confirmation signal SPSIG having a second value corresponding to a second case, that is, a case that the program suspend operation begins in a state TS2 in which the number of the cells whose threshold voltage level has reached the target level among the program cells is one or more and less than or equal to a predetermined number.

For yet another example, the suspend operation detector 411 may generate a suspend confirmation signal SPSIG having a third value corresponding to a third case, that is, a case that the program suspend operation begins in a state TS3 in which the number of the cells whose threshold voltage level has reached the target level among the program cells exceeds a predetermined number.

When it is required to perform the set logic operation for both first data DATA1 and second data DATA2 according to the suspend confirmation signal SPSIG, the operation executer 412 included in the control logic 402 may read the second data DATA2 stored in the program cells and store the read second data DATA2 in a plurality of second latches 423. Also, the operation executer 412 may perform the set logic operation corresponding to the suspend confirmation signal SPSIG on the first data DATA1 stored in the first latches 422 and the second data DATA2 stored in the second latches 423 to repair the input data INPUT_DATA. Also, the operation executer 412 may store the temporary data TEMP_DATA generated in the process of performing the set logic operation corresponding to the suspend confirmation signal SPSIG on the first data DATA1 and the second data DATA2 in the third latches 424.

The operation executer 412 included in the control logic 402 may not read the second data DATA2 stored in the program cells when it is required to perform the set logic operation only on the first data DATA1 according to the suspend confirmation signal SPSIG. Also, the operation executer 412 may perform the set logic operation corresponding to the suspend confirmation signal SPSIG only on the first data DATA1 stored in the first latches 422 to repair the input data INPUT_DATA.

To be more specific, referring to FIG. 5A together with FIG. 4, the operation executer 412 may read (RD) the second data DATA2 stored in the program cells in response to the suspend confirmation signal SPSIG having the second value or the third value and store the read second data DATA2 in the second latches 423.

The operation executer 412 may store the second data DATA2 in the second latches 423 and perform a first repair operation of generating the intermediate repair data MD_RP_DATA by performing one logic operation on the first data DATA1 stored in the first latches 422. The one logic operation may include a logic operation corresponding to the suspend confirmation signal SPSIG, among the first logic operation LOGIC<1> and the second logic operation LOGIC<2>. Here, the operation executer 412 may generate the intermediate repair data MD_RP_DATA by performing the first logic operation LOGIC<1> on the first data DATA1 stored in the first latches 422 in response to the suspend confirmation signal SPSIG having the second value. The operation executer 412 may generate the intermediate repair data MD_RP_DATA by performing the second logic operation LOGIC<2> on the first data DATA1 stored in the first latches 422 in response to the suspend confirmation signal SPSIG having the third value. The operation executer 412 may convert the first data DATA1 stored in the first latches 422 into the intermediate repair data MD_RP_DATA through one logic operation among the first logic operation LOGIC<1> and the second logic operation LOGIC<2>. Each of the first logic operation LOGIC<1> and the second logic operation LOGIC<2> may generate the temporary data TEMP_DATA during the logic operation. Therefore, the temporary data TEMP_DATA may be stored in the third latches 424.

Referring to FIG. 5B together with FIG. 4, after the first repair operation is completed, that is, after the intermediate repair data MD_RP_DATA is stored in the first latches 422, the operation executer 412 may repair the input data INPUT_DATA by performing a third logic operation LOGIC<3> on the intermediate repair data MD_RP_DATA of the first latches 422 and the second data DATA2 of the second latches 423. The operation executer 412 may convert the intermediate repair data MD_RP_DATA stored in the first latches 422 into the input data INPUT_DATA through the third logic operation LOGIC<3>. The third logic operation LOGIC<3> may generate the temporary data TEMP_DATA during the logic operation. Therefore, the temporary data TEMP_DATA may be stored in the third latches 424.

Referring to FIG. 5C together with FIG. 4, the operation executer 412 may repair the input data INPUT_DATA by performing a fourth logic operation LOGIC<4> on the first data DATA1 of the first latches 422 in response to the suspend confirmation signal SPSIG having the first value. The operation executer 412 may repair the first data DATA1 of the first latches 422 to generate the input data INPUT_DATA through the fourth logic operation LOGIC<4>. The operation executer 412 may not read the second data DATA2 stored in the program cells in response to the suspend confirmation signal SPSIG having the first value. The second latches 423 may be empty. Here, in the case of the fourth logic operation LOGIC<4>, the temporary data TEMP_DATA may not be generated during the logic operation. Therefore, no data may be stored in the third latches 424.

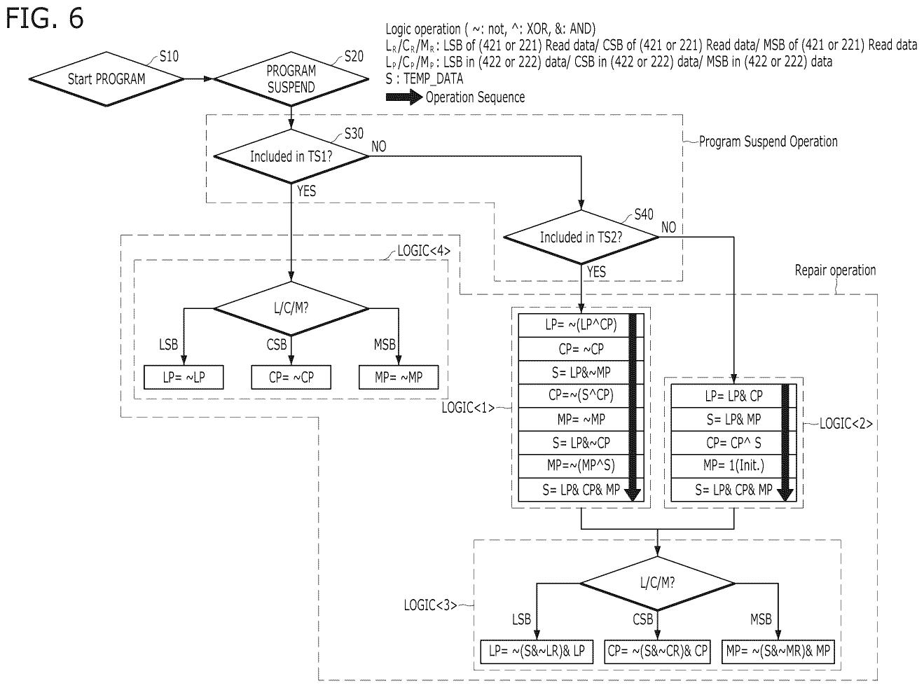

FIG. 6 illustrates an operation sequence of a repair operation during a program suspend operation and a set logic operation applied to the repair operation in accordance with an embodiment of the present disclosure.

Referring to FIG. 6, the operation sequence of a repair operation during a program suspend operation in accordance with the embodiment of the present disclosure is as follows.

First, a program operation for programming the input data stored in a page buffer into a memory cell selected as a program target (which is, hereinafter, referred to as ‘a program cell’) may be performed in S10. In S10, the value of the input data stored in the page buffer may be changed as the program operation is performed. In this way, the input data whose value is changed according to the progress of the program operation may be the first data (see the description related to FIG. 7 described above).

After S10, a program suspend operation may be requested in S20.

When the operation S20 is requested, a repair operation for repairing the input data whose value is changed according to the progress of the program operation in the operation S10, that is, the first data, back into the input data may be performed. As a result of performing a repair operation of executing a set logic operation on at least one data among the first data stored in the page buffer and the second data stored in the memory cell selected as a program target, the first data stored in the page buffer may be repaired to generate the input data.

After the operation S20 is requested, before the repair operation is performed, a suspend confirmation operation of detecting at what moment during the program operation the operation S20 is requested and selecting the type of the set logic operation LOGIC<1:4> to be applied to the repair operation based on the detection result may be performed.

In the suspend confirmation operation, when it is required to perform the set logic operation on both first data stored in the page buffer and second data stored in the memory cell selected as the program target, the repair operation may include a first repair operation and a second repair operation. The first repair operation may include an operation of generating the intermediate repair data out of the first data stored in the page buffer by performing one logic operation among the first logic operation LOGIC<1> and the second logic operation LOGIC<2> on the first data stored in the page buffer. The second repair operation may include an operation of repairing the intermediate repair data stored in the page buffer to generate the input data by performing the third logic operation LOGIC<3> on the intermediate repair data stored in the page buffer through the first repair operation.

When it is required to perform a set logic operation only on the first data stored in the page buffer in the suspend confirmation operation, the repair operation may include an operation of repairing the input data by performing the fourth logic operation LOGIC<4> on the first data stored in the page buffer.

To be specific, the suspend confirmation operation may include an operation S30 of checking whether the beginning moment of the operation S20 is included in the state TS1 during the program operation. Here, the state TS1 may mean a state that there are no cells whose threshold voltage level has reached the target level among the program cells (see the description related to FIG. 8 described above).

When it is determined that the beginning moment of the operation S20 is not included in the state TS1 during the program operation (NO in S30), the suspend confirmation operation may include an operation S40 for detecting whether the beginning moment of the operation S20 is included in the state TS2 during the program operation. Here, the state TS2 may mean a state in which the number of the cells whose threshold voltage level has reached the target level among program cells is one or more and less than or equal to a predetermined number (see the description related to FIG. 8 described above).

The program operation may be divided into the state TS1 to the state TS3, and the case where the beginning moment of the operation S20 is not included in the state TS2 during the program operation (NO in S40) may mean a case that the beginning moment of the operation S20 is included in the state TS3 during the program operation. Here, the state TS3 may mean a state in which the number of the cells whose threshold voltage level has reached the target level among the program cells exceeds the predetermined number (see the description related to FIG. 8 described above).

In the case where the beginning moment of the operation S20 is included in the state TS1 during the program operation (YES in S30), the type of the set logic operation to be applied to the repair operation may be determined as the fourth logic operation LOGIC<4>.

The fourth logic operation LOGIC<4> may include a logic operation of inverting the value of the first data stored in the page buffer in order to repair the first data to generate the input data. For example, when the program cell is a triple-level cell TLC, an inversion operation (˜) may be performed onto LSB data LP, CSB data CP, and MSB data MP included in the first data through the fourth logic operation LOGIC<4> to generate repaired data, i.e., the LSB data ˜LP, CSB data ˜CP, and MSB data ˜MP included in the input data.

In the case where the beginning moment of the operation S20 is included in the state TS3 during the program operation (YES in S40), the type of the set logic operation to be applied to the repair operation may be determined as the first logic operation LOGIC<1>and the third logic operation LOGIC<3>. The first logic operation LOGIC<1> may be performed on the first data stored in the page buffer to repair the intermediate repair data, and the third logic operation LOGIC<3> may be performed on the intermediate repair data to repair the input data.

In the case where the beginning moment of the operation S20 is not included in the state TS3 during the program operation (NO in S40), the type of the set logic operation to be applied to the repair operation may be determined as the second logic operation LOGIC<2> and the third logic operation LOGIC<3>. The second logic operation LOGIC<2> may be performed on the first data stored in the page buffer to repair the intermediate repair data, and the third logic operation LOGIC<3> may be performed on the intermediate repair data to repair the input data.

In some embodiments, when the program cell is a triple-level cell TLC, the first logic operation LOGIC<1> may be performed in the following order.

First, a value obtained by performing an inverse operation (˜) on the value (LP\hat{ }CP) obtained by performing an exclusive OR (XOR) operation (\hat{ }) on the LSB data LP and the CSB data CP of the first data may be defined (LP=˜(LP\hat{ }CP)) as the value of the LSB data LP of the intermediate repair data.

Subsequently, a value obtained by performing an inverse operation (˜) on the CSB data CP of the first data may be re-defined (CP=˜CP) as the value of the CSB data CP of the first data.

Subsequently, a value obtained by performing an AND operation (&) on a value (˜MP) obtained by performing an inverse operation (˜) on the MSB data MP of the first data and the LSB data LP of the intermediate repair data may be defined (S=LP&˜MP) as the temporary data S.

Subsequently, a value (˜(S\hat{ }CP)) obtained by performing an inverse operation (˜) on a value (S\hat{ }CP) obtained by performing an exclusive OR operation (\hat{ }) on the temporary data S and the CSB data CP of the first data may be defined (CP=˜(S\hat{ }CP)) as the value of the CSB data CP of the intermediate repair data.

Subsequently, a value (˜MP) obtained by performing an inverse operation (˜) on the MSB data MP of the first data may be re-defined (MP=˜MP) as the value of the MSB data MP of the first data.

Subsequently, a value (LP&˜CP) obtained by performing an AND operation (&) on the value (˜CP) obtained by performing an inverse operation (˜) on the CSB data CP of the intermediate repair data, and the LSB data LP of the intermediate repair data may be defined (S=LP&˜CP) as the temporary data S.

Subsequently, a value (˜(MP\hat{ }S)) obtained by performing an inverse operation (˜) on a value (MP\hat{ }S) obtained by performing an exclusive OR operation (\hat{ }) on the MSB data MP of the first data and the temporary data S may be re-defined (MP=˜(MP\hat{ }S)) as the value of the MSB data MP of the intermediate repair data.

Subsequently, a value obtained by performing an AND operation (&) on the LSB data LP, the CSB data CP and the MSB data MP of the intermediate repair data may be defined (S=LP&CP&MP) as the temporary data S.

In some embodiments, when the program cell is a triple-level cell TLC, the second logic operation LOGIC<2> may be performed in the following order.

First, a value (LP&CP) obtained by performing an AND operation (&) on the LSB data LP of the first data and the CSB data CP of the first data may be defined (LP=LP&CP) as the LSB data LP of the intermediate repair data.

Subsequently, a value (LP&MP) obtained by performing an AND operation (&) on the LSB data LP of the intermediate repair data and the MSB data MP of the first data may be defined (S=LP&MP) as the temporary data S.

Subsequently, a value (CP\hat{ }S) obtained by performing an exclusive OR operation (\hat{ }) on the CSB data CP of the first data and the temporary data S may be defined (CP=CP\hat{ }S) as the CSB data CP of the intermediate repair data.

Subsequently, a value of the MSB data MP of the intermediate repair data may be defined and initialized (MP=1 (Init.)) as the initial value ‘1’.

Subsequently, a value obtained by performing an AND operation (&) on the LSB data LP, the CSB data CP, and the MSB data MP of the intermediate repair data may be defined (S=LP& CP& MP) as the temporary data S.

In some embodiments, when the program cell is a triple-level cell TLC, the third logic operation LOGIC<3> may be performed as follows.

A value (˜(S&˜LR)& LP) obtained by performing an AND operation (&) on a value (˜(S&˜LR)), which is obtained by performing an inverse operation (˜) on a value (S&˜LR), and the LSB data LP of the intermediate repair data may be defined (LP=˜(S&˜LR)&LP) as the value of the LSB data LP of the input data. The value (˜(S&˜LR)) may be obtained by performing an inverse operation (˜) on a value (S&˜LR) obtained by performing an AND operation (&) on the temporary data S and a value (˜LR) obtained by performing an inverse operation (˜) on the LSB data LR of the second data.

A value (˜(S&˜CR)&CP) may be defined (CP=˜(S&˜CR)&CP) as the value of the CSB data CP of the input data. The value (˜(S&˜CR)&CP) may be obtained by performing an AND operation (&) on the CSB data CP of the intermediate repair data and a value (˜(S&˜CR). The value (˜(S&˜CR) may be obtained by performing an inverse operation (˜) on a value (S&˜CR) obtained by performing an AND operation (&) on the value (˜CR) and the temporary data S. The value (˜CR) may be obtained by performing an inverse operation (˜) on the CSB data CR of the second data.

A value (˜(S&˜MR)&MP) may be defined (MP=˜(S&˜MR)&MP) as the MSB data MP of the input data. The value (˜(S&˜MR)&MP) may be obtained by performing an AND operation (&) on a value (˜(S&˜MR)) and the MSB data MP of the intermediate repair data. The value (˜(S&˜MR) may be obtained by performing an inverse operation (˜) on a value (S&˜MR), which is obtained by performing an AND operation (&) on the temporary data S and a value (˜MR) obtained by performing an inverse operation (˜) on the MSB data MR of the second data.

According to the embodiment of the present disclosure, when a program suspend operation is performed in the middle of a program operation, the input data may be repaired by using a number of logic operations that may be applied differently according to the result of detecting the moment when the program suspend operation begins to be performed.

In this way, the resources required for an input data repair operation when the program suspend operation is performed, for example, the physical data storage space required for the repair operation and the time required for the repair operation, may be minimized, and the quality of service (QOS) may be optimized.

While the embodiments of the present disclosure have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A memory system comprising:
a memory device including a plurality of memory cells coupled between a plurality of word lines and a plurality of bit lines and a plurality of latches coupled to the bit lines, and configured to:
program input data stored in the latches into memory cells of a selected word line during a program operation, and
output, as information data, at least one or more data among first data stored in the latches and second data stored in the memory cells of the selected word line during a program suspend operation for suspending the program operation; and
a controller configured to:
repair the input data by performing a set logic operation on the information data from the memory device, and
apply the set logic operation whose type is different according to an execution moment of the program suspend operation.

2. The memory system of claim 1, wherein the controller includes:
first and second buffers;
a suspend operation detector configured to detect the execution moment of the program suspend operation to produce a detection result and generate a suspend confirmation signal based on the detection result; and
an operation executer configured to store the information data in the first buffer, repair the information data of the first buffer to generate the input data by performing the set logic operation corresponding to the suspend confirmation signal on the information data, and store, in the second buffer, temporary data generated by performing the set logic operation.

3. The memory system of claim 2, wherein the controller further includes a request generator configured to generate and transfer one request among a first request and a second request as the information data to the memory device in response to the suspend confirmation signal, the first request requesting for the first data, the second request requesting for both first data and second data.

4. The memory system of claim 3, wherein, when the second request is received from the controller,
the memory device outputs, to the controller, the first data stored in the latches, reads the second data from the memory cells to store in the latches and outputs the second data in the latches to the controller.

5. The memory system of claim 4, wherein, when the first request is received from the controller,
the memory device outputs, to the controller, the first data stored in the latches and does not read the second data from the memory cells.

6. The memory system of claim 3, wherein the operation executer allocates, in the first buffer, two spaces for storing the first data and the second data in response to the suspend confirmation signal, and performs:
a first repair operation for repairing the first data of the first buffer to generate intermediate repair data by storing, in the first buffer, the first and second data input from the memory device and then performing one logic operation on the first data stored in the first buffer, the one logic operation corresponding to the suspend confirmation signal among a first logic operation and a second logic operation, and
a second repair operation for repairing the intermediate repair data of the first buffer to generate the input data by performing a third logic operation on the intermediate repair data and the second data after the first repair operation is completed.

7. The memory system of claim 6, wherein the operation executer allocates, in the first buffer, one space for storing the first data in response to the suspend confirmation signal, stores, in the first buffer, the first data input from the memory device, and performs a fourth logic operation on the first data to repair the first data of the first buffer to generate the input data.

8. The memory system of claim 7, wherein the suspend operation detector detects the number of cells whose threshold voltage level has reached a target level among the memory cells of the selected word line to produce the detection result, and generates the suspend confirmation signal based on the detection result.

9. The memory system of claim 8, wherein the operation executer
determines that the fourth logic operation is required to be performed on the first data in response to the suspend confirmation signal corresponding to a case where there are no cells whose threshold voltage level has reached the target level among the memory cells of the selected word line,
determines that the first logic operation is required to be performed on the first data and the third logic operation is required to be performed on the second data in response to the suspend confirmation signal corresponding to a case where the number of the cells whose threshold voltage level has reached the target level among the memory cells of the selected word line is one or more and less than or equal to a predetermined number, and
determines that the second logic operation is required to be performed on the first data and the third logic operation is required to be performed on the second data in response to the suspend confirmation signal corresponding to a case where the number of the cells whose threshold voltage level has reached the target level among the memory cells of the selected word line exceeds the predetermined number.

10. A memory device comprising:
a memory cell array including a plurality of memory cells coupled between a plurality of word lines and a plurality of bit lines;
a page buffer including a plurality of first latches corresponding to the bit lines, respectively; and
a control logic configured to:
program input data stored in the first latches into memory cells of a selected word line during a program operation,
repair the input data by performing a set logic operation on at least one or more data among first data and second data during a program suspend operation for suspending the program operation, the first data stored in the first latches, the second data stored in the memory cells of the selected word line, and
apply the set logic operation whose type is different according to an execution moment of the program suspend operation.

11. The memory device of claim 10, wherein the page buffer further includes a plurality of second latches and a plurality of third latches respectively corresponding to the bit lines, and
the control logic includes:
a suspend operation detector configured to detect the execution moment of the program suspend operation to produce a detection result and generate a suspend confirmation signal based on the detection result; and
an operation executer configured to read the second data from the memory cells of the selected word line and store the read second data in the second latches, perform the set logic operation corresponding to the suspend confirmation signal on the first and second data stored in the first and second latches, respectively, and store, in the third latches, temporary data generated by performing the set logic operation, when the set logic operation is required to be performed on both first data and second data according to the suspend confirmation signal.

12. The memory device of claim 11, wherein, when the set logic operation is required to be performed on the first data according to the suspend confirmation signal,
the operation executer performs the set logic operation corresponding to the suspend confirmation signal on the first data stored in the first latches without reading the second data from the memory cells of the selected word line.

13. The memory device of claim 11, wherein, when the set logic operation is required to be performed on both first data and second data according to the suspend confirmation signal,
the operation executer performs
a first repair operation of repairing the first data of the first latches to generate intermediate repair data by performing one logic operation on the first data stored in the first latches, the one logic operation corresponding to the suspend confirmation signal among the first logic operation and the second logic operation, and
a second repair operation of repairing the intermediate repair data of the first latches to generate the input data by performing a third logic operation on the intermediate repair data stored in the first latches and the second data stored in the second latches, after the first repair operation is completed.

14. The memory device of claim 13, wherein, when the set logic operation is required to be performed on the first data according to the suspend confirmation signal,
the operation executer repairs the first data of the first latches to generate the input data by performing a fourth logic operation on the first data stored in the first latches.

15. The memory device of claim 14, wherein the suspend operation detector detects the number of cells whose threshold voltage level has reached a target level among the memory cells of the selected word line to produce the detection result and generates the suspend confirmation signal based on the detection result.

16. The memory device of claim 15, wherein the operation executer
determines that the fourth logic operation is required to be performed on the first data in response to the suspend confirmation signal corresponding to a case where there are no cells whose threshold voltage level has reached the target level among the memory cells of the selected word line,
determines that the first logic operation is required to be performed on the first data and the third logic operation is required to be performed on the second data in response to the suspend confirmation signal corresponding to a case where the number of the cells whose threshold voltage level has reached the target level among the memory cells of the selected word line is one or more and less than or equal to a predetermined number, and
determines that the second logic operation is required to be performed on the first data and the third logic operation is required to be performed on the second data in response to the suspend confirmation signal corresponding to a case where the number of the cells whose threshold voltage level has reached the target level among the memory cells of the selected word line exceeds the predetermined number.

17. A method for operating a memory device, the method comprising:
performing a program operation of programming input data stored in a page buffer into a memory cell selected as a program target;
repairing the input data by performing a set logic operation on at least one data among first data stored in the page buffer and second data stored in the selected memory cell during a program suspend operation after the program operation; and
detecting an execution moment of the program suspend operation to produce a detection result and selecting a type of the set logic operation to be applied to the repairing of the input data based on the detection result.

18. The method of claim 17, wherein the repairing of the input data includes:
performing a first repair operation of repairing the first data to generate intermediate repair data by performing one logic operation among a first logic operation and a second logic operation on the first data stored in the page buffer, when the set logic operation is required to be performed on both first data and second data in the detecting of the execution moment of the program suspend operation; and
performing a second repair operation of repairing the intermediate repair data to generate the input data by performing a third logic operation on the intermediate repair data stored in the page buffer and the second data stored in the selected memory cell after the first repair operation.

19. The method of claim 18, wherein repairing the input data further includes:
performing a third repair operation of repairing the input data by performing a fourth logic operation on the first data stored in the page buffer, when the set logic operation is required to be performed on the first data in the detecting of the execution moment of the program suspend operation.

20. The method of claim 19, wherein repairing the input data further includes:
determining that the fourth logic operation is required to be performed on the first data, when the execution moment of the program suspend operation is detected in a program operation of a state in which there are no cells whose threshold voltage level has reached a target level among the selected memory cells;
determining that the first logic operation is required to be performed on the first data and the third logic operation is required to be performed on the second data, when the execution moment of the program suspend operation is detected in a program operation of a state in which the number of the cells whose threshold voltage level has reached a target level among the selected memory cells is one or more and less than or equal to a predetermined number; and
determining that the second logic operation is required to be performed on the first data and the third logic operation is required to be performed on the second data, when the execution moment of the program suspend operation is detected in a program operation of a state in which the number of the cells whose threshold voltage level has reached the target level among the selected memory cells exceeds the predetermined number.
